(19) United States
(12) Patent Application Publication
(10) Pub. No.: US 2009/0178842 A1
(43) Pub. Date: Jul. 16, 2009

(54) Adhesive patch structure for absorbing and shielding electromagnetic waves

(76) Inventor: Hung-Tao Liu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/219,337

(22) Filed: Jul. 21, 2008

(30) Foreign Application Priority Data
Jan. 10, 2008 (TW) 097200644

(51) Int. Cl. H05K 9/00

(52) U.S. Cl. 174/389

(57) ABSTRACT

An adhesive patch structure for absorbing and shielding electromagnetic waves is disclosed, wherein a preformed transparent or translucent adhesive patch is provided therein or on at least one surface thereof with a mineral material-based layer of a mineral composition rich in negative electromagnetic energy. The mineral material-based layer generates an energy field capable of absorbing or shielding ambient hazardous electromagnetic waves.

### BACKGROUND OF THE INVENTION

1. Technical Field

The present invention relates to an adhesive patch structure for absorbing and shielding electromagnetic waves, and more particularly, to an adhesive patch structure wherein a preformed transparent or translucent adhesive patch is provide therein or on at least one surface thereof with a mineral material-based layer of a mineral composition rich in negative electromagnetic energy. The mineral material-based layer generates an energy field capable of absorbing or shielding ambient hazardous electromagnetic waves.

2. Description of Related Art

It has been scientifically proved that all energy-driven or energy-generating objects or substances emit electromagnetic waves. For example, electronic products such as television sets, computers, cell phones, electric lamps, electric hair dryers and microwave stoves emit electromagnetic waves. In addition, natural minerals (precious stones), various metal oxides, magnets, dielectric ceramic materials and soft magnetic materials containing high-density metals were successively found in recent years to be capable of generating energy fields. Depending on their radiation power and frequencies, electromagnetic waves may have totally different effects on human body. For instance, high-power and high-frequency electromagnetic waves may cause mutation in deoxyribonucleic acid (DNA) or chromosomes when acting on an organic body (living body) at a short distance. On the other hand, when an organic body is radiated mildly by low-power and low-frequency electromagnetic waves, the possibility of cell mutation may be significantly reduced, thereby benefiting the organic body. More particularly, it has been verified that several of the aforementioned natural minerals (such as those having negative electromagnetic energy) can convert harmful (high-power, high-frequency) electromagnetic waves in the environment into beneficial (low-power, low-frequency) electromagnetic waves, which lends more value of use to such minerals.

Therefore, inventive products were constantly developed in recent years, and proven effective to certain extent, to eliminate or shield electromagnetic waves emitted by everyday electric appliances, so as to minimize the damage these appliances may cause to human body. For instance, Taiwan Patent Nos. 456692, 563086, 399826 and 427603 provide “leather jacket for cell phone”; Taiwan Patent Nos. 508067, 430241 and 478727 teach “device for absorbing electromagnetic waves”; Taiwan Patent Nos. 526704, 449257 and 361747 disclose “telephone casing”; and Taiwan Patent No. M292265 reveals “clothing for eliminating static electricity and electromagnetic waves”. However, a compact, simple and transparent adhesive patch for reducing static electricity and electromagnetic waves is yet to be seen. Although materials designed to serve the purpose are available, they are either too large to be used without further cutting, or comprise a non-transparent metal oxide layer that prevents their being applied to a surface that must not be opaquely covered, such as the front side of a display device. As a result, those materials are difficult to use and may not be applied to the front side of an electronic product whose electromagnetic waves are to be absorbed or shielded.

### BRIEF SUMMARY OF THE INVENTION

In order to solve the aforementioned problems, a gel patch is made of a transparent gel material and has at least one surface coated with a very thin powder coating layer, wherein the powder coating layer comprises a coating material mixed with a translucent mineral powder having energy (such as a coating material mixed with a mineral powder having negative electromagnetic energy). The gel patch is further coated, on at least one surface thereof, with an adhesive, so that the entire structure is still transparent to some extent and can be directly adhered at any desired location on a front side of an electronic product, including a display device, so as to absorb and shield static electricity or electromagnetic waves in that particular direction.

Another feature of the present invention is that the aforesaid gel patch is configured to have one side centrally formed with a raised portion and the other side formed with a flat surface. In other words, the gel patch is disk-shaped and thinner towards a periphery thereof. The flat side is coated with the powder coating layer and then covered with the adhesive. Therefore, when the gel patch is adhered to an object, the powder coating layer is shielded and protected from falling off. Furthermore, when the gel patch is adhered to an object, the relatively thin outer periphery of the gel patch provides a smooth touch at an edge of the adhered area, so that the gel patch will not be easily peeled off by an external force.

### BRIEF DESCRIPTION OF THE SEVERAL VIEWS OF THE DRAWINGS

The physical structure and effects of the present invention can be best understood by referring to the following detailed description of the preferred embodiment and the accompanying drawings, wherein:

FIG. 1 is a schematic perspective view of the present invention;

FIG. 2 is a side view of the present invention;

FIG. 3 is a schematic drawing showing the present invention being applied to a front side of a cell phone;

FIG. 4 is a schematic drawing showing the present invention being applied to a rear side of a cell phone; and

FIG. 5 is a schematic drawing showing the present invention being applied to a front side of a display device.

### DETAILED DESCRIPTION OF THE INVENTION

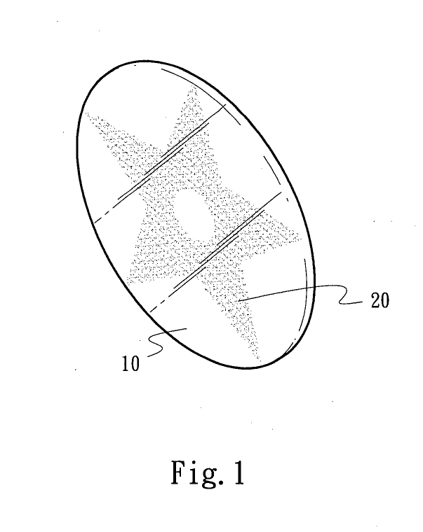

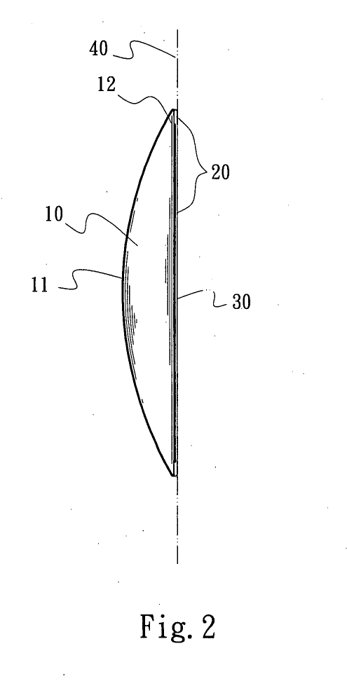

Referring to FIGS. 1 and 2, the present invention comprises a transparent gel patch 10 has at least one surface coated with a very thin powder coating layer 20 composed of a coating material mixed with a translucent mineral powder having energy (such as a coating material mixed with a mineral powder having negative electromagnetic energy). In addition, the transparent gel patch 10 has at least one surface coated with a transparent adhesive layer 30. The gel patch 10 is disk-shaped and has a relatively thick central portion 11 and a relatively thin peripheral portion 12, with one side centrally formed with a raised portion and the other side formed with a flat surface. Therefore, when adhered to a surface of an electronic product 40, the gel patch 10 still exhibits proper toughness and transparency, and provides a smooth touch. More specifically, the powder coating layer 20 is coated on the flat side to a very small thickness, and then covered with the transparent adhesive layer 30. Hence, the transparent adhesive layer 30 not only serves to adhere, but also protects the powder coating layer 20 from falling off. Once adhered to a surface of the electronic product 40, the relatively thin peripheral portion 12 provides a smooth touch while the relatively thick central portion 11 furnishes sufficient physical support so that the gel patch 10 will not be too pliable. As a whole, the central portion 11 and the peripheral portion 12 can prevent the gel patch 10 from being easily peeled off by an external force acting on the peripheral portion 12.

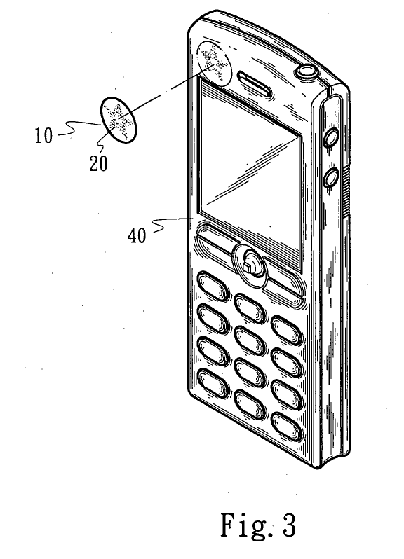

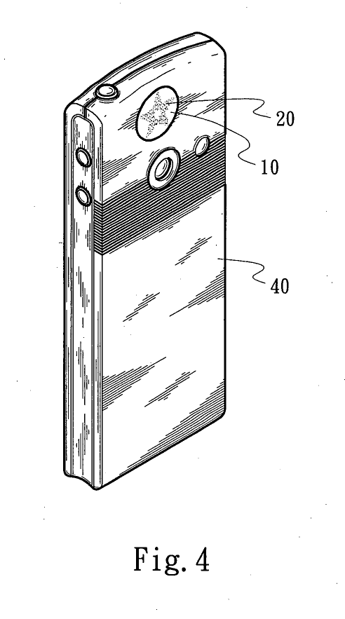

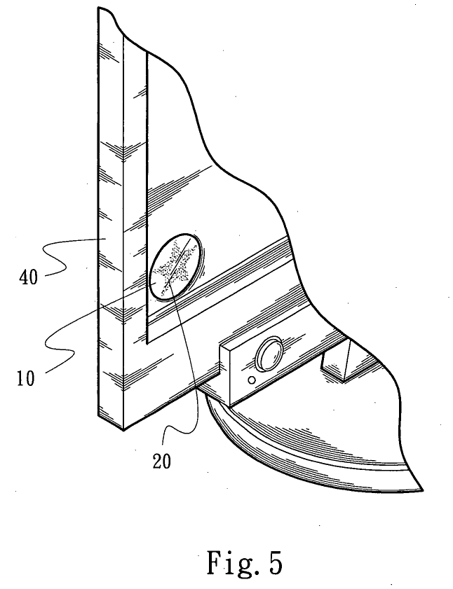

Referring to FIGS. 3 to 5, the adhesive patch structure having the aforesaid configuration for absorbing and shielding electromagnetic waves can be directly adhered to a surface of an electronic product 40 emitting electromagnetic waves, such as a cell phone in FIGS. 3 and 4 and a display device in FIG. 5, thereby creating a barrier between the electronic product 40 and its user for absorbing and shielding electromagnetic waves. Thus, energy of hazardous electromagnetic waves can be absorbed, reduced and converted into beneficial electromagnetic waves to eliminate possible damages to the user.

In conclusion, the present invention provides a convenient and useful adhesive patch structure for absorbing and shielding electromagnetic waves. The embodiment disclosed herein is intended to facilitate illustration of the present invention, rather than limit the form thereof. Therefore, any partial alterations or modifications which do not depart from the spirit of the present invention should be construed as within the scope of the present invention, which is defined by the appended claims.

1. An adhesive patch structure for absorbing and shielding electromagnetic waves, comprising a transparent gel patch with at least one surface coated with a powder coating layer containing a translucent mineral powder capable of emitting energy, wherein the gel patch further has at least one surface coated with a transparent adhesive layer.

2. The adhesive patch structure for absorbing and shielding electromagnetic waves of claim 1, wherein the gel patch is disk-shaped and has a relatively thick central portion and a relatively thin peripheral portion.

3. The adhesive patch structure for absorbing and shielding electromagnetic waves of claim 1, wherein the gel patch has one side centrally formed with a raised portion and another side formed with a flat surface.

4. The adhesive patch structure for absorbing and shielding electromagnetic waves of claim 2, wherein the gel patch has one side centrally formed with a raised portion and another side formed with a flat surface.

5. The adhesive patch structure for absorbing and shielding electromagnetic waves of claim 3, wherein the powder coating layer containing the translucent mineral powder is coated on the flat surface, and the adhesive layer is coated on the flat surface which has been coated with the powder coating layer.

6. The adhesive patch structure for absorbing and shielding electromagnetic waves of claim 4, wherein the powder coating layer containing the translucent mineral powder is coated on the flat surface, and the adhesive layer is coated on the flat surface which has been coated with the powder coating layer.

7. The adhesive patch structure for absorbing and shielding electromagnetic waves of claim 1, wherein the mineral powder has negative electromagnetic energy.

8. The adhesive patch structure for absorbing and shielding electromagnetic waves of claim 2, wherein the mineral powder has negative electromagnetic energy.

9. The adhesive patch structure for absorbing and shielding electromagnetic waves of claim 3, wherein the mineral powder has negative electromagnetic energy.

10. The adhesive patch structure for absorbing and shielding electromagnetic waves of claim 4, wherein the mineral powder has negative electromagnetic energy.

11. The adhesive patch structure for absorbing and shielding electromagnetic waves of claim 5, wherein the mineral powder has negative electromagnetic energy.

12. The adhesive patch structure for absorbing and shielding electromagnetic waves of claim 6, wherein the mineral powder has negative electromagnetic energy.
